(19) United States
(12) Patent Application Publication
(10) Pub. No.: US 2022/0149596 A1
(43) Pub. Date: May 12, 2022

(54) SEMICONDUCTOR LASER DEVICE

(71) Applicant: PANASONIC CORPORATION, Osaka (JP)

(72) Inventors: Masaharu Fukakusa, Osaka (JP); Hideo YAMAGUCHI, Kyoto (JP); Koshi NAKAMURA, Osaka (JP)

(21) Appl. No.: 17/441,681

(22) PCT Filed: Mar. 5, 2020
(86) PCT No.: PCT/JP2020/009309

§ 371 Date: Sep. 21, 2021

(30) Foreign Application Priority Data
Mar. 25, 2019 (JP) 2019-056901

(51) Int. Cl. H01S 5/40; H01S 5/02253; H01S 5/02326

(52) U.S. Cl. CPC H01S 5/4012; H01S 5/02326; H01S 5/02253

(57) ABSTRACT

The semiconductor laser device includes: semiconductor laser elements; lenses; a deflection element; a wavelength dispersion element that wavelength-couples emitted light beams to form coupled light; and a partial reflection mirror. The lenses include a first lens that reduces a divergence angle of the emitted light beams in a first axis direction, and a second lens that is disposed between the first lens and the wavelength dispersion element and reduces the divergence angle of the laser beams in a second axis direction. The deflection element has planes each corresponding to the emitted light beams, at least one plane among the planes is inclined with respect to an optical axis of a corresponding one of the emitted light beams, which corresponds to each of the at least one plane, and the emitted light beams overlap one another on the wavelength dispersion element.

### TECHNICAL FIELD

The present disclosure relates to a semiconductor laser device including a plurality of semiconductor laser elements.

### BACKGROUND ART

As semiconductor laser devices with excellent directional properties, those that can obtain light output exceeding 1 watt have been developed, and a laser beam source device capable of outputting light having about several hundred watts or more and several thousand watts or less by bundling laser beam from a large number of semiconductor laser elements has been proposed. These semiconductor laser devices that can obtain high light output are used, for example, as a heat source for processing by irradiating the workpiece. For example, these semiconductor laser devices are used for welding metal materials, cutting metal plates, and the like. As a method of bundling laser beam from a large number of semiconductor laser elements, for example, there is space coupling or wavelength coupling, and a coupling optical system has been devised in order to obtain high-luminance laser beam.

For example, in the laser assembly described in Patent Literature (PTL) 1, a plurality of semiconductor laser elements are radially arranged around a predetermined position in a plane including the fast axis. With this, the laser beam is to be focused at a predetermined position.

In addition, in the laser device described in PTL 2, laser beams having different wavelengths from a plurality of laser modules are focused on a diffraction grating using a lens and wavelength-coupled.

### CITATION LIST

### Patent Literature

[PTL 1] Japanese Unexamined Patent Application Publication No. 2011-86905
[PTL 2] International Publication No. WO2017/134911

### SUMMARY OF INVENTION

### Technical Problem

However, in the laser assembly described in PTL 1, since a plurality of semiconductor laser elements are arranged radially, the plurality of laser assemblies must be arranged separated from each other. Along with this, since the number of laser elements that can be arranged within a predetermined angle range is limited, the light output is also limited.

In addition, in the laser device described in PTL 2, the laser beam from each module focused by the lens is incident on the diffraction grating. Each of the laser beam incident on the diffraction grating is not parallel light but convergent light. Since the laser beam wavelength-coupled by the diffraction grating is only the laser beam having an incident angle corresponding to the oscillation wavelength of each module, the component of the laser beam having no predetermined angle among the convergent light diverges after it is emitted from the diffraction grating. For this reason, a coupling loss occurs when the laser beam emitted from the diffraction grating is focused by the lens and incident on the optical fiber. Furthermore, in the coupling to the optical fiber having a smaller diameter, the coupling loss further increases. In addition, since the laser beam is focused on the diffraction grating by the lens, the light density on the diffraction grating is very high, and the diffraction grating may be destroyed. For this reason, there is also a limit to the number of laser beams that can be coupled, and it is difficult to increase the output.

The present disclosure solves such problems, and in a semiconductor laser device that performs wavelength coupling by a wavelength dispersion element, the semiconductor laser device is provided, which can emit a high-luminance laser beam while suppressing the light density in the wavelength dispersion element.

### Solution to Problem

In order to solve the above problems, one aspect of the semiconductor laser device according to the present disclosure includes: semiconductor laser elements each of which emits a light beam having a different wavelength; a deflection element that deflects at least one of emitted light beams emitted from the semiconductor laser elements; and a wavelength dispersion element that wavelength-couples the emitted light beams onto a same optical axis, wherein the deflection element has planes each corresponding to the emitted light beams; and the emitted light beams overlap one another on the wavelength dispersion element.

With this, even if the plurality of semiconductor laser elements are arranged so that the interval therebetween is small, a plurality of emitted light beams can be overlapped on the wavelength dispersion element by appropriately setting the inclination of the plurality of planes of the deflection element. With this, since the number of semiconductor laser elements per unit area can be increased, the number of semiconductor laser elements that can be arranged in the semiconductor laser device can also be increased, and the increased output of the semiconductor laser device can be realized. In addition, since the plurality of emitted light beams are not converged by the deflection element, they can be incident on the wavelength dispersion element in the state of parallel light. Therefore, since the beam diameter on the wavelength dispersion element can be increased, even if a plurality of emitted light beams are overlapped, the light density can be suppressed as compared with the case where a plurality of converged light beams are overlapped. With this, it is possible to overlap the emitted light beams from more semiconductor laser elements while suppressing damage to the wavelength dispersion element, so that the increased output of the semiconductor laser device can be realized.

In addition, since each laser beam incident on the wavelength dispersion element can be made into parallel light having a small incident angle distribution, each laser beam can be combined in the state of parallel light by the wavelength dispersion element. With this, a high-luminance laser beam with high beam quality can be obtained as the emitted light output from the partial reflection mirror.

In addition, in one aspect of the semiconductor laser device according to the present disclosure, the emitted light beams each have a divergence angle in a first axis direction and a divergence angle in a second axis direction orthogonal to the first axis direction, the semiconductor laser device further includes lenses each of which converts at least one of the divergence angle in the first axis direction or the divergence angle in the second axis direction, at least one plane among the planes is inclined with respect to an optical axis of a corresponding one of the emitted light beams, and the semiconductor laser elements may be arranged in one axis direction of the first axis direction and the second axis direction.

In this way, at least one plane of the plurality of planes is inclined with respect to the optical axis of the corresponding one of the emitted light beams, so that the corresponding one of the emitted light beams can be deflected.

In addition, one aspect of the semiconductor laser device according to the present disclosure may further include a partial reflection mirror that reflects a part of the emitted light beams wavelength-coupled by the wavelength dispersion element, transmits another part of the emitted light beams, and forms an external resonator with the semiconductor laser elements.

In addition, in one aspect of the semiconductor laser device according to the present disclosure, the lenses may include a first lens that reduces the divergence angle of a laser beam in the first axis direction.

In addition, in one aspect of the semiconductor laser device according to the present disclosure, the lenses may include a second lens that reduces the divergence angle of the emitted light beams in the second axis direction.

In addition, in one aspect of the semiconductor laser device according to the present disclosure, the second lens may be disposed between the first lens and the wavelength dispersion element.

In addition, in one aspect of the semiconductor laser device according to the present disclosure, a beam parameter product of each of the emitted light beams may be 1 [mm·mrad] or less in the one axis direction.

In this case, the beam parameter product in the axis direction, in which the plurality of emitted light beams are overlapped, of the two axis directions of the plurality of emitted light beams, is 1 [mm·mrad] or less, so that even if the overlap of the respective emitted light beams is deviated, the allowable range of deviation becomes large. With this, the deterioration of the beam quality in the axis direction coupled by the wavelength dispersion can be suppressed, so that a semiconductor laser device capable of outputting a high-luminance laser beam can be realized.

In addition, in one aspect of the semiconductor laser device according to the present disclosure, the deflection element has an incident surface on which the emitted light beams are incident, and an emitting surface from which the emitted light beams incident on the incident surface are emitted, and the planes are transmission surfaces that transmit the emitted light beams, and may be included in at least one of the incident surface or the emitting surface.

In addition, in one aspect of the semiconductor laser device according to the present disclosure, the planes may be reflective surfaces that reflect the emitted light beams, respectively.

In addition, in one aspect of the semiconductor laser device according to the present disclosure, the one axis direction is the first axis direction, the first lens is a fast axis collimator, and the second lens may be a slow axis collimator.

In addition, one aspect of the semiconductor laser device according to the present disclosure further includes: packages in each of which a corresponding one of the semiconductor laser elements is mounted, and which comprise a metal material, wherein each of the packages includes lead pins that supply electric power to the semiconductor laser element mounted in the package among the semiconductor laser elements are included, the first lens is disposed at each of light emission portions of the packages, each of the packages has a mounting surface on which the semiconductor laser element is mounted, and each of the packages includes two planes parallel to the mounting surface, and a distance between the two planes corresponds to a thickness of the package, and may be equal to each of intervals at which the semiconductor laser elements are arranged.

In addition, in one aspect of the semiconductor laser device according to the present disclosure, the semiconductor laser elements are mounted in the packages via sub-mounts comprising a conductive material, one of the lead pins has a potential identical to a potential of the packages, and the semiconductor laser elements may be voltage-driven.

In addition, in one aspect of the semiconductor laser device according to the present disclosure, the semiconductor laser elements are each mounted in corresponding one of the packages via a corresponding one of sub-mounts comprising an electrically insulating material, the lead pins are insulated from a corresponding one of the packages, and the semiconductor laser elements may be current-driven.

In addition, in one aspect of the semiconductor laser device according to the present disclosure, the packages may each airtightly seal a corresponding one of the semiconductor laser elements.

With this, the atmosphere inside the package can be controlled, so that deterioration of the semiconductor laser elements can be suppressed. In particular, when the semiconductor laser elements emit laser beams having a relatively short wavelength such as blue light or ultraviolet light, the deposition of siloxane onto the semiconductor laser elements or the like can be reduced by suppressing the inflow of siloxane into the package.

In addition, in one aspect of the semiconductor laser device according to the present disclosure, a beam parameter product of each of the emitted light beams in the first axis direction and the second axis direction is 1 [mm·mrad] or less, the semiconductor laser elements are arranged in the second axis direction, the first lens is a fast axis collimator, and the second lens may be a slow axis collimator.

In this case, the beam parameter product in the axis direction, in which the emitted light beams are overlapped, of the two axis directions of the plurality of emitted light beams, is 1 [mm·mrad] or less, so that even if the overlap of the respective emitted light beams is deviated, the allowable range of deviation becomes large. With this, the beam quality in the axis direction coupled by the wavelength dispersion can be maintained, so that a semiconductor laser device capable of outputting a high-luminance laser beam can be realized.

In addition, one aspect of the semiconductor laser device according to the present disclosure further includes: one package in which the semiconductor laser elements are mounted, and which comprises a metal material, wherein the one package includes lead pins that supply electric power to the semiconductor laser elements, and the first lens is disposed in the one package.

In addition, in one aspect of the semiconductor laser device according to the present disclosure, the semiconductor laser elements may be mounted in the one package via one sub-mount.

In this way, by mounting a plurality of semiconductor laser elements on one sub-mount, it is possible to reduce the deviation of the optical axes of the plurality of emitted light beams. Therefore, the semiconductor laser device can output a laser beam having higher luminance.

In addition, in one aspect of the semiconductor laser device according to the present disclosure, the one package may airtightly seal the semiconductor laser elements.

With this, the atmosphere inside the package can be controlled, so that deterioration of the semiconductor laser elements can be suppressed. In particular, when the semiconductor laser elements emit laser beams having a relatively short wavelength such as blue light or ultraviolet light, the deposition of siloxane onto the semiconductor laser elements or the like can be reduced by suppressing the inflow of siloxane into the package.

### Advantageous Effects of Invention

According to the present disclosure, in a semiconductor laser device that performs wavelength coupling by a wavelength dispersion element, it is possible to provide a semiconductor laser device that can emit high-luminance laser beam while suppressing the light density in the wavelength dispersion element.

### BRIEF DESCRIPTION OF DRAWINGS

FIG. 1A is a schematic top view showing the overall configuration of a semiconductor laser device according to Embodiment 1.

FIG. 1B is a schematic side view showing the overall configuration of the semiconductor laser device according to Embodiment 1.

FIG. 2A is a perspective view showing the appearance on the upper surface side of a light source unit according to Embodiment 1.

FIG. 2B is a perspective view showing the appearance on the lower surface side of the light source unit according to Embodiment 1.

FIG. 2C is an exploded perspective view showing a configuration of the light source unit according to Embodiment 1.

FIG. 3A is a perspective view showing the appearance of a light source module according to Embodiment 1.

FIG. 3B is a component development diagram showing a configuration of the light source module according to Embodiment 1.

FIG. 4A is a perspective view showing the appearance of a deflection element according to Embodiment 1.

FIG. 4B is a side view and a top view showing the shape of the deflection element according to Embodiment 1.

FIG. 5 is a diagram for explaining the operation and effect of the semiconductor laser device according to Embodiment 1.

FIG. 6A is a graph showing a first design example of a plurality of planes of the deflection element according to Embodiment 1.

FIG. 6B is a graph showing a second design example of a plurality of planes of the deflection element according to Embodiment 1.

FIG. 6C is a graph showing a third design example of a plurality of planes of the deflection element according to Embodiment 1.

FIG. 6D is a graph showing a fourth design example of a plurality of planes of the deflection element according to Embodiment 1.

FIG. 7 is a schematic top view showing the configuration of the light source unit according to Embodiment 2.

FIG. 8 is a schematic top view showing the configuration of the semiconductor laser device according to Embodiment 2.

FIG. 9 is a schematic top view showing the configuration of the semiconductor laser device according to Embodiment 3.

FIG. 10 is a schematic perspective view showing the appearance of the light source unit according to Embodiment 4.

FIG. 11 is an exploded perspective view showing the configuration of the light source unit according to Embodiment 4.

FIG. 12 is an exploded perspective view showing the configuration of the light source module according to Embodiment 4.

FIG. 13 is a perspective view showing the appearance of a plurality of semiconductor laser devices and sub-mounts according to Embodiment 4.

### DESCRIPTION OF EMBODIMENTS

Hereinafter, embodiments of the present disclosure will be described with reference to the drawings. It should be noted that each of the embodiments described below shows a specific example of the present disclosure. Therefore, the numerical values, shapes, materials, components, arrangement positions and connection forms of the components, and the like shown in the following embodiments are examples and are not intended to limit the present disclosure. Therefore, among the components in the following embodiments, the components not described in the independent claims indicating the broadest concept of the present disclosure will be described as arbitrary components.

In addition, each figure is a schematic diagram and is not necessarily exactly illustrated. Therefore, the scales and the like do not always match in each figure. It should be noted that in each figure, substantially the same configuration is designated by the same reference numerals, and duplicate description will be omitted or simplified.

In addition, in the present specification and drawings, the X-axis, Y-axis, and Z-axis represent the three axes of the three-dimensional Cartesian coordinate system. The X-axis and the Y-axis are orthogonal to each other and both are orthogonal to the Z-axis.

### Embodiment 1

The semiconductor laser device according to Embodiment 1 will be described.

### [Overall Structure]

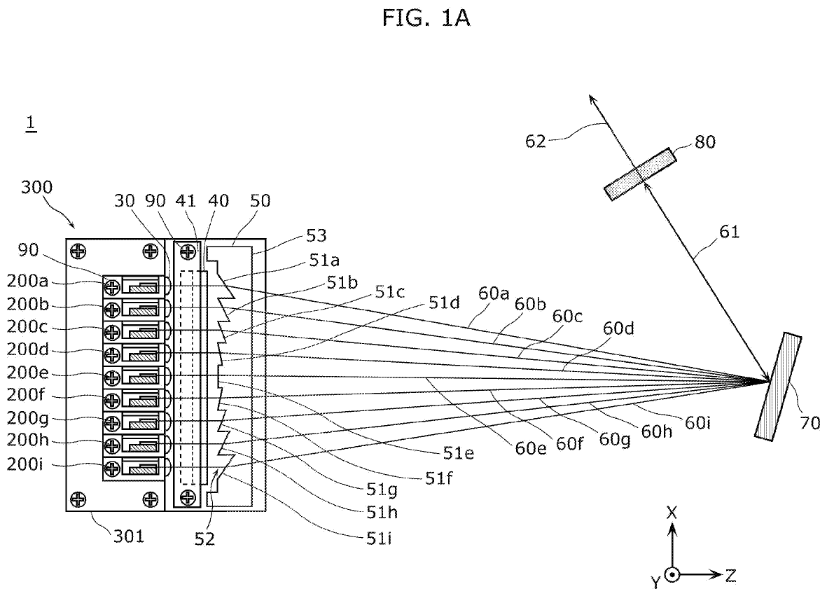

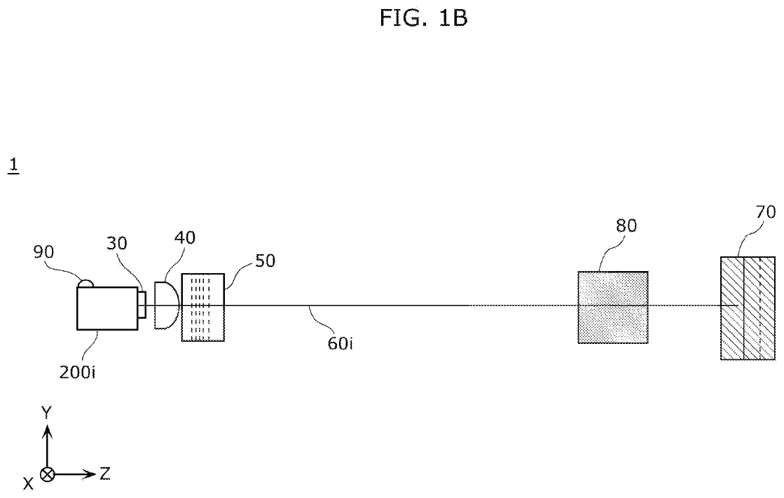

First, the overall configuration of the semiconductor laser device according to the present embodiment will be described with reference to FIG. 1A and FIG. 1B. FIG. 1A and FIG. 1B are schematic top view and side view that show the overall configuration of semiconductor laser device 1 according to the present embodiment, respectively.

Semiconductor laser device 1 according to the present embodiment is a laser beam source that performs wavelength coupling of a plurality of emitted light beams by a wavelength dispersion element. As shown in FIG. 1A and FIG. 1B, semiconductor laser device 1 includes light source unit 300, wavelength dispersion element 70, and partial reflection mirror 80.

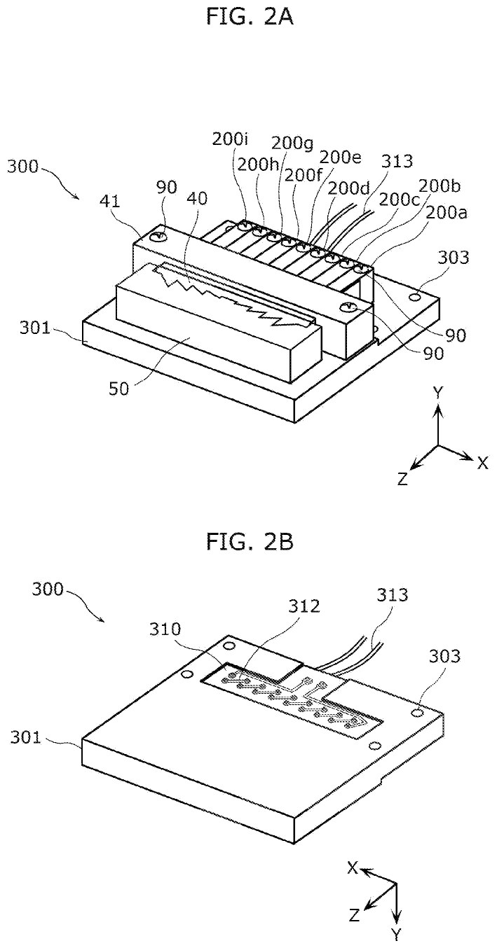

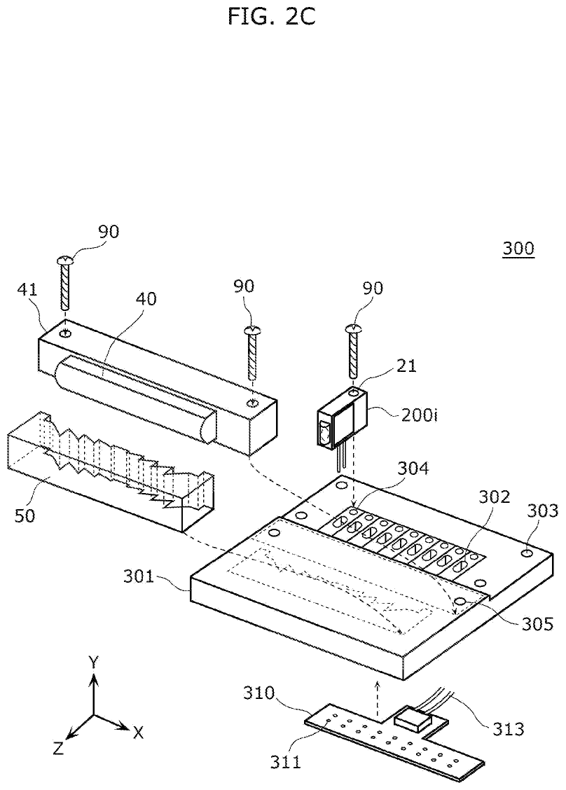

Light source unit 300 is a unit including a plurality of semiconductor laser elements. Light source unit 300 will be described with reference to FIG. 2A to FIG. 2C. FIG. 2A and FIG. 2B are perspective views showing the appearance of the upper surface side and the lower surface side of light source unit 300 according to the present embodiment, respectively. FIG. 2C is an exploded perspective view showing the configuration of light source unit 300 according to the present embodiment.

As shown in FIG. 2A and FIG. 2C, light source unit 300 includes a plurality of light source modules 200a to 200i, second lens 40, lens holder 41, deflection element 50, and unit base 301. It should be noted that in FIG. 1B described above, the illustration of unit base 301 and lens holder 41 is omitted for the sake of simplicity. In addition, in FIG. 2C, only light source module 200i is shown among the plurality of light source modules 200a to 200i. In addition, as shown in FIG. 2B and FIG. 2C, light source unit 300 further includes circuit board 310.

Unit base 301 is a base of light source unit 300, and a plurality of light source modules 200a to 200i and the like are attached to unit base 301. As shown in FIG. 2C, unit base 301 has a plate-like shape. Unit base 301 is formed with fixing holes 304 and 305 and through holes 302 and 303. Fixing hole 304 is a screw hole into which screw 90 for fixing each of the plurality of light source modules 200a to 200i is screwed. Fixing hole 305 is a screw hole into which screw 90 for fixing lens holder 41 is screwed. Through hole 302 is an elongated hole into which lead pins 23 and 24 of each of the plurality of light source modules 200a to 200i are inserted. Through hole 303 is a hole into which a screw or the like for fixing unit base 301 is inserted.

Circuit board 310 is a board that supplies electric power to the plurality of light source modules 200a to 200i. As shown in FIG. 2B and FIG. 2C, circuit board 310 is arranged on the back surface of unit base 301 (that is, the surface behind the surface on which each light source module or the like is arranged). Power supply lead 313, which is a lead wire for supplying electric power to circuit board 310, is connected to circuit board 310. Circuit board 310 is formed with through holes 311 for connecting respective lead pins 23 and 23 of the plurality of light source modules 200a to 200i. In addition, printed wiring 312 from electric power supply lead 313 to through hole 311 and the like are formed on circuit board 310, and power is supplied from electric power supply lead 313 to lead pins 23 and 24 via that printed wiring 312. In the example shown in FIG. 2B, printed wiring 312 in the case where a plurality of light source modules 200a to 200i are connected in series and the same current is supplied thereto, that is, in the case where they are current-driven is shown. It should be noted that circuit board 310 may include a circuit for converting at least one of the voltage or the current supplied from electric power supply lead 313.

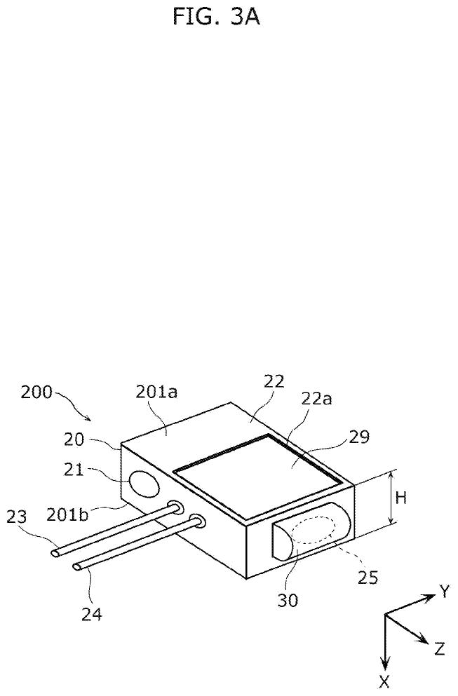

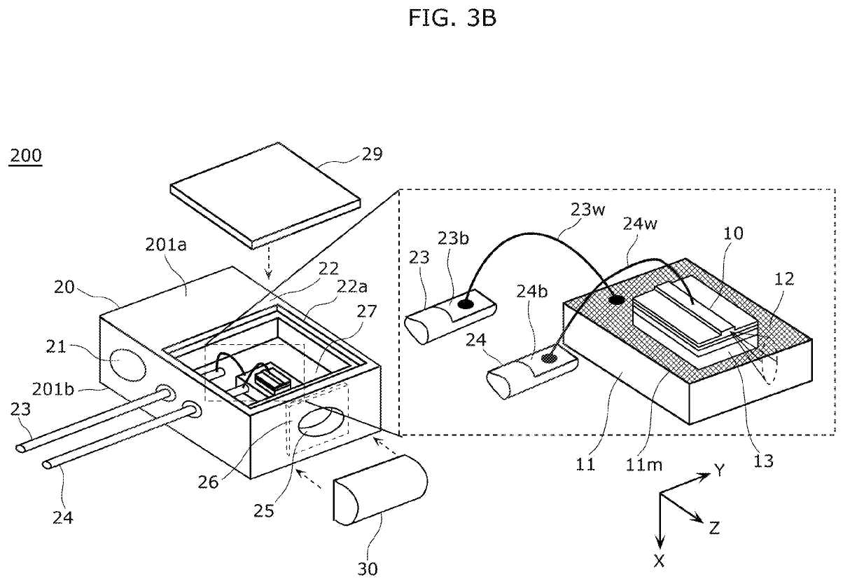

Each of the plurality of light source modules 200a to 200i is a module including a semiconductor laser element. It should be noted that light source unit 300 according to the present embodiment includes nine light source modules 200a to 200i, but the number of light source modules is not particularly limited as long as it is plural. Hereinafter, the configuration of the plurality of light source modules 200a to 200i will be described with reference to FIG. 3A and FIG. 3B. FIG. 3A is a perspective view showing the appearance of light source module 200 according to the present embodiment. FIG. 3B is a component development view showing the configuration of light source module 200 according to the present embodiment. In FIG. 3B, an enlarged view in the broken line frame near semiconductor laser element 10 is also shown. Each of the plurality of light source modules 200a to 200i shown in FIG. 1A has the same configuration as light source module 200 shown in FIG. 3A and FIG. 3B.

As shown in FIG. 3A and FIG. 3B, light source module 200 includes package 20 and first lens 30. In the present embodiment, as shown in FIG. 3B, light source module 200 includes semiconductor laser element 10, sub-mount 11, and cover glass 26. Package 20 is a case in which semiconductor laser element 10 is mounted and comprises a metal material. Package 20 includes frame body 22, lid 29, and a plurality of lead pins 23 and 24.

Frame body 22 is the main body of package 20, and has opening 22a, light emission portion 25, and through hole 21 formed therein. Opening 22a is an opening connected to the inside of package 20, and is an insertion port for inserting semiconductor laser element 10 or the like into package 20. In the present embodiment, opening 22a has a rectangular shape. Light emission portion 25 is an opening formed on one surface of frame body 22, and the emitted light from semiconductor laser element 10 mounted inside package 20 passes through light emission portion 25. First lens 30 is arranged in light emission portion 25. Lid 29 is a plate-shaped member that closes opening 22a of frame body 22, and has a rectangular shape like opening 22a. Each of lead pins 23 and 24 is a terminal for supplying electric power to semiconductor laser element 10. Through hole 21 is a hole into which screw 90 for fixing package 20 to unit base 301 is inserted. Screw 90 inserted into through hole 21 is screwed into fixing hole 304 which is a screw hole formed in unit base 301 as shown in FIG. 2C. With this, light source module 200 is fixed to unit base 301. In addition, when light source module 200 is fixed to unit base 301, lead pins 23 and 24 are inserted into through holes 302 of unit base 301 and further inserted into through holes 311 of circuit board 310 shown in FIG. 2C. Lead pins 23 and 24 inserted into through holes 311 of circuit board 310 are fixed to circuit board 310 by using solder or the like, and are electrically connected to printed wiring 312.

As shown in FIG. 3B, package 20 includes mounting surface 27 on which semiconductor laser element 10 is mounted. In addition, package 20 includes two planes 201a and 201b parallel to mounting surface 27, and the distance between two planes 201a and 201b corresponds to thickness H of package 20 (see FIG. 3A). In the present embodiment, as shown in FIG. 1A and FIG. 2A, the plurality of light source modules 200a to 200i are arranged in the thickness direction of package 20 with almost no gap. That is, thickness H of package 20 is equal to the interval at which the plurality of semiconductor laser elements 10 are arranged. Here, in the configuration that the description that thickness H of package 20 is equal to the interval at which the plurality of semiconductor laser elements 10 are arranged means, not only the configuration in which thickness H of package 20 completely matches the interval at which semiconductor laser elements 10 are arranged, but also the configuration in which thickness H of package 20 substantially matches the interval at which semiconductor laser elements 10 are arranged are included. In the configuration that the description that thickness H of package 20 is equal to the interval at which the plurality of semiconductor laser elements 10 are arranged means, for example, a configuration in which the error between thickness H of package 20 and the interval at which semiconductor laser element 10 is arranged is within 5% may be included.

In addition, by arranging light source modules 200a to 200i on unit base 301 as described above, the optical axes of the plurality of emitted light beams from the plurality of semiconductor laser elements 10 exist in the same plane. In the example shown in FIG. 1A and the like, the optical axes of the plurality of emitted light beams exist in a plane parallel to the ZX plane. Here, in the configuration that the description that the optical axes of the plurality of emitted light beams are present in the same plane means, not only the configuration in which each of the optical axes is present completely in the same plane but also the configuration in which each of the optical axes is present substantially in the same plane are included. In the configuration that the description that the optical axes of the plurality of emitted light beams are present in the same plane means, the configuration in which the optical axes of the plurality of emitted light beams are deviated from a predetermined plane by a degree due to manufacturing error, assembly error, or the like may also be included. For example, a configuration in which the deviation in the direction of each optical axis is about 5° or less may be included, and a configuration in which the deviation of the position of each optical axis from a predetermined plane is about 20% or less of the spot size of each of the emitted light beams may also be included.

Package 20 comprises, for example, a metal material. It should be noted that insulating members are inserted between lead pins 23 and 24 and frame body 22. With this, it is possible to prevent lead pins 23 and 24 from conducting with frame body 22 and the like. Lead pins 23 and 24 each have a rod-like shape, and one end thereof is arranged inside package 20 and the other end is arranged outside package 20 through frame body 22 of package 20. Bonding surface 23b is planar in shape is formed at the one end of lead pin 23 which is disposed inside package 20, and bonding surface 24b which is planar in shape is formed at the one end of lead pin 24 which is disposed inside package 20. One end of first conductive wire 23w is bonded to bonding surface 23b, and one end of second conductive wire 24w is bonded to bonding surface 24b. The other end of first conductive wire 23w is bonded to conductive film 12 formed on sub-mount 11. With this, first conductive wire 23w is connected to the n-side electrode of semiconductor laser element 10 via conductive film 12. In addition, the other end of second conductive wire 24w is connected to semiconductor laser element 10. More specifically, the other end of second conductive wire 24w is connected to the p-side electrode of semiconductor laser element 10.

In addition, in the present embodiment, package 20 airtightly seals semiconductor laser element 10. That is, the space between opening 22a of frame body 22 and lid 29, the space between light emission portion 25 and cover glass 26, and the like are sealed. With this, the atmosphere inside package 20 can be controlled, so that the deterioration of semiconductor laser elements 10 can be suppressed. In particular, when semiconductor laser elements 10 emit laser beams having a relatively short wavelength such as blue light or ultraviolet light, the deposition of siloxane onto semiconductor laser elements 10 or the like can be reduced by suppressing the inflow of siloxane into package 20.

Semiconductor laser elements 10 are semiconductor light emitting elements that emit emitted light beams, and emit light beams having different wavelengths from one another. In the present embodiment, semiconductor laser element 10 has a high reflectance reflective film (not shown) formed at one end in the laser resonance direction, and low-reflection film 13 formed at the other end as shown in FIG. 3B.

The plurality of emitted light beams from the plurality of semiconductor laser elements 10 have divergence angles in the first axis direction and the second axis direction. In the present embodiment, the first axis direction and the second axis direction are a fast axis direction and a slow axis direction, respectively. In addition, in the example shown in FIG. 3B and the like, the first axis direction is parallel to the X-axis direction, and the second axis direction is orthogonal to the first axis direction, and is parallel to the Y-axis direction. In the present embodiment, the plurality of semiconductor laser elements 10 are arranged in the first axis direction as shown in FIG. 1A and FIG. 2A. More specifically, the plurality of semiconductor laser elements 10 are arranged at equal intervals in the first axis direction. The configuration of semiconductor laser elements 10 is not particularly limited, but for example, semiconductor laser elements 10 are laser elements comprising a GaN-based semiconductor material.

Sub-mount 11 is a member mounted on mounting surface 27 of package 20. Semiconductor laser element 10 is mounted on sub-mount 11. That is, semiconductor laser element 10 is mounted on package 20 via sub-mount 11. More specifically, semiconductor laser element 10 is mounted on one main surface of sub-mount 11. In the present embodiment, the n-side electrode of semiconductor laser element 10 is mounted on upper surface 11m of sub-mount 11.

Conductive film 12 is formed on upper surface 11m of sub-mount 11, and is connected to the n-side electrode of semiconductor laser element 10.

In the present embodiment, sub-mount 11 comprises an electrically insulating material having high thermal conductivity. Sub-mount 11 comprises, for example, SiC, AlN, diamond, or the like. Since the heat conductivity of sub-mount 11 is high, the heat generated by semiconductor laser element 10 can be quickly dissipated, so that adverse effects such as output reduction due to the heat of semiconductor laser element 10 can be suppressed. In addition, by sub-mount 11 comprising an electrically insulating material, the n-side electrode of semiconductor laser element 10 and package 20 can be insulated. With this, for example, a plurality of semiconductor laser elements 10 can be connected in series to be current-driven.

Cover glass 26 is a translucent plate-shaped member arranged in light emission portion 25 of package 20. In the present embodiment, cover glass 26 is a transparent glass plate that covers light emission portion 25.

First lens 30 is one of the plurality of lenses that convert the divergence angle of the emitted light beam from semiconductor laser element 10, and reduces the divergence angle of the emitted light beam in the first axis direction. In the present embodiment, first lens 30 reduces the divergence of semiconductor laser element 10 in the fast axis direction. In the present embodiment, first lens 30 makes the emitted light beam of semiconductor laser element 10 parallel light in the fast axis direction. That is, first lens 30 is a fast axis collimator. In addition, the first axis direction is the fast axis direction. First lens 30 is a cylindrical lens comprising, for example, glass, quartz, or the like. First lens 30 is disposed at light emission portion 25 of package 20 via cover glass 26.

Second lens 40 is one of the plurality of lenses that convert the divergence angle of the emitted light beam from semiconductor laser element 10, is disposed between first lens 30 and wavelength dispersion element 70, and reduces the divergence angle of the laser beam in the second axis direction. In the present embodiment, second lens 40 reduces the divergence of semiconductor laser element 10 in the slow axis direction. In the present embodiment, second lens 40 makes the emitted light beam of semiconductor laser element 10 parallel light in the slow axis direction. That is, second lens 40 is a slow axis collimator. In addition, the second axis direction is the slow axis direction. Second lens 40 is a cylindrical lens comprising, for example, glass or quartz.

Lens holder 41 is a holder that holds second lens 40. Lens holder 41 is fixed to unit base 301 by screws 90. That is, second lens 40 is fixed to unit base 301 via lens holder 41. Lens holder 41 comprises, for example, a metal material like package 20.

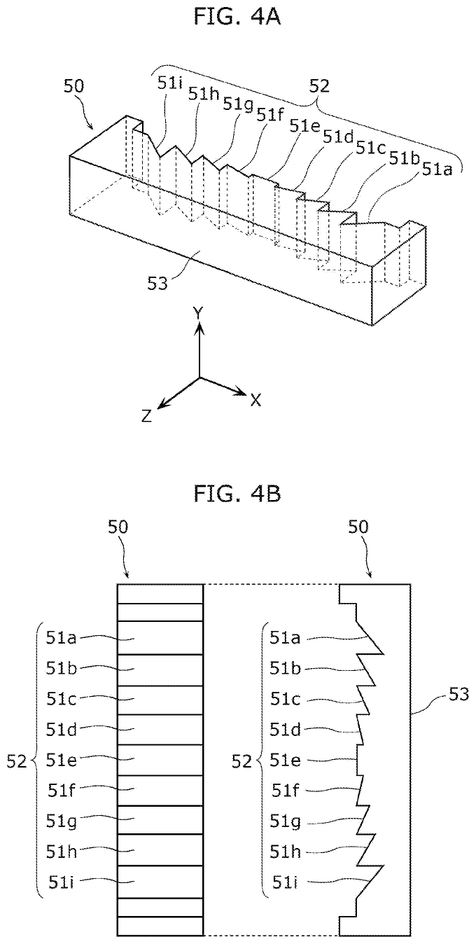

Deflection element 50 is an optical element that deflects at least one of the plurality of emitted light beams from the plurality of semiconductor laser elements 10. Deflection element 50 is fixed to unit base 301. The mode of fixing deflection element 50 to unit base 301 is not particularly limited. In the present embodiment, the bottom surface of deflection element 50 (that is, the surface facing unit base 301) is bonded to unit base 301. Deflection element 50 is bonded to unit base 301 using, for example, an adhesive or the like. Hereinafter, deflection element 50 will be described in detail with reference to FIG. 1A, FIG. 4A and FIG. 4B. FIG. 4A is a perspective view showing the appearance of deflection element 50 according to the present embodiment. FIG. 4B is a side view and a top view showing the shape of deflection element 50 according to the present embodiment. In FIG. 4B, a side view and a top view of deflection element 50 are shown on the left side and the right side, respectively.

As shown in FIG. 1A, deflection element 50 includes incident surface 52 on which the plurality of emitted light beams 60a to 60i from the plurality of semiconductor laser elements 10 are incident, and emitting surface 53 from which the plurality of emitted light beams 60a to 60i incident from incident surface 52 are emitted. In addition, deflection element 50 includes a plurality of planes 51a to 51i corresponding to the plurality of emitted light beams. In the present embodiment, the plurality of planes 51a to 51i are transmission surfaces that transmit the plurality of emitted light beams 60a to 60i, respectively. It should be noted that in the present embodiment, the plurality of planes 51a to 51i are included in incident surface 52, but the plurality of planes 51a to 51i may be included in emitting surface 53. The plurality of planes 51a to 51i may be included in at least one of incident surface 52 or emitting surface 53.

Each of at least one plane of the plurality of planes 51a to 51i of deflection element 50 is inclined with respect to an optical axis of an emitted light beam, of the plurality of emitted light beams 60a to 60i, which corresponds to each of the at least one plane. In the present embodiment, as shown in FIG. 1A, planes 51a to 51d and 51f to 51i are inclined (i.e., not vertical) with respect to the corresponding emitted light beams 60a to 60d and 60f to 60i, respectively. In addition, the inclination of each plane increases as the distance from plane 51e increases. With this, in deflection element 50, the farther the emitted light beam is from emitted light beam 60e, the greater the deflection by deflection element 50. In addition, since the plurality of emitted light beams 60a to 60i exist in the same plane, deflection element 50 makes it possible to overlap the plurality of emitted light beams 60a to 60i on wavelength dispersion element 70. The detailed operation of deflection element 50 will be described later. Deflection element 50 comprises, for example, a translucent material such as glass, quartz, or the like. The shape of the inclined surface of deflection element 50 can be formed, for example, by molding a glass material using a mold. Alternatively, it can also be formed by a method for forming the shape by transferring the shape to the resist applied onto the glass substrate by a stepper device or the like using a grayscale mask or the like having a transmittance corresponding to the shape of the inclined surface, and then etching the glass substrate by a reactive etching device (RIE) or the like. Antireflection films for increasing the transmittance are formed on incident surface 52 and emitting surface 53 of deflection element 50 formed in this way. The antireflection film, which is obtained by laminating a plurality of dielectric materials having different refractive indexes (for example, materials such as SiO₂, TiO₂, Al₂O₃, Ta₂O₃, and Nb₂O₅) in multiple layers by, for example, sputtering or vapor deposition, is used.

Wavelength dispersion element 70 is an optical element in which a plurality of emitted light beams 60a to 60i from deflection element 50 are wavelength-coupled on the same optical axis to form coupled light beam 61. The configuration of wavelength dispersion element 70 is not particularly limited as long as it is an optical element capable of wavelength-coupling the plurality of emitted light beams 60a to 60i on the same optical axis, but in the present embodiment, wavelength dispersion element 70 is a reflective diffraction grating. Here, the configuration that the description that a plurality of emitted light beams 60a to 60i are wavelength-coupled on the same optical axis means includes not only a configuration in which a plurality of emitted light beams 60a to 60i are coupled on completely the same optical axis but also a configuration in which a plurality of emitted light beams 60a to 60i are coupled on substantially the same optical axis. The configuration that the description that a plurality of emitted light beams 60a to 60i are wavelength-coupled on the same optical axis means may include a configuration in which each optical axis of a plurality of wavelength-coupled emitted light beams 60a to 60i is deviated to some extent due to manufacturing errors and assembly errors. For example, the case where the deviation in the direction of each optical axis is about 5° or less may be included, and the case where the deviation of the position of each optical axis is about 20% or less of the spot size of each of the emitted light beams may also be included.

The wavelengths of the plurality of emitted light beams 60a to 60i incident on wavelength dispersion element 70 are different from one another, and are determined based on the angle of incidence on wavelength dispersion element 70, the emitting angle of coupled light beam 61, and the characteristics of wavelength dispersion element 70.

Partial reflection mirror 80 is an element that reflects a part of coupled light beam 61 from wavelength dispersion element 70, transmits the other part, and forms an external resonator with a plurality of semiconductor laser elements 10. More specifically, partial reflection mirror 80 forms an external resonator with a high reflection film formed on the plurality of semiconductor laser elements 10. In the present embodiment, partial reflection mirror 80 is a plane mirror. The reflective film having the partial reflection characteristic of partial reflection mirror 80 is formed on one surface of partial reflection mirror 80, and an antireflection film is formed on the other surface. As the reflective film and the antireflection film, for example, a dielectric multilayer film obtained by laminating a plurality of dielectric materials having different refractive indexes (for example, materials such as SiO₂, TiO₂, Al₂O₃, Ta₂O₃, and Nb₂O₅) in multiple layers by sputtering or vapor deposition is used. The reflectance of partial reflection mirror 80 is appropriately set according to the characteristics of the plurality of semiconductor laser elements 10 and the like, but may be substantially constant in the width of the wavelength at which each of the plurality of semiconductor laser elements 10 oscillates, and specifically, may be substantially constant in the width of a center wavelength of −20 nm or more and a center wavelength of +20 nm or less. In order to increase the output of semiconductor laser device 1, laser beam 62 output through partial reflection mirror 80 should be as large as possible. In order to increase the output of laser beam 62, the reflectance of partial reflection mirror 80 may be set in the range of 5% to 50%

### [Operation and Effect]

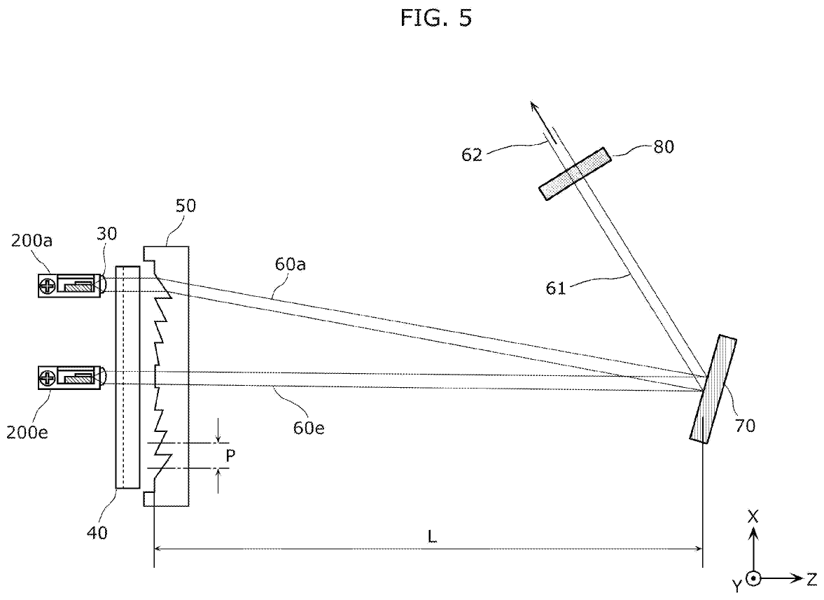

Next, the operation and effect of semiconductor laser device 1 according to the present embodiment will be described with reference to FIG. 5. FIG. 5 is a diagram for explaining the operation and effect of semiconductor laser device 1 according to the present embodiment. In FIG. 5, for simplification, only light source modules 200a and 200e are shown among the plurality of light source modules 200a to 200i.

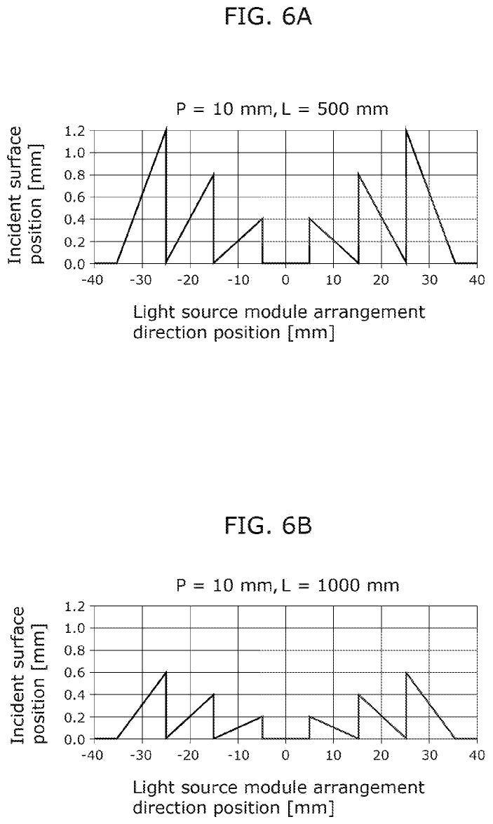

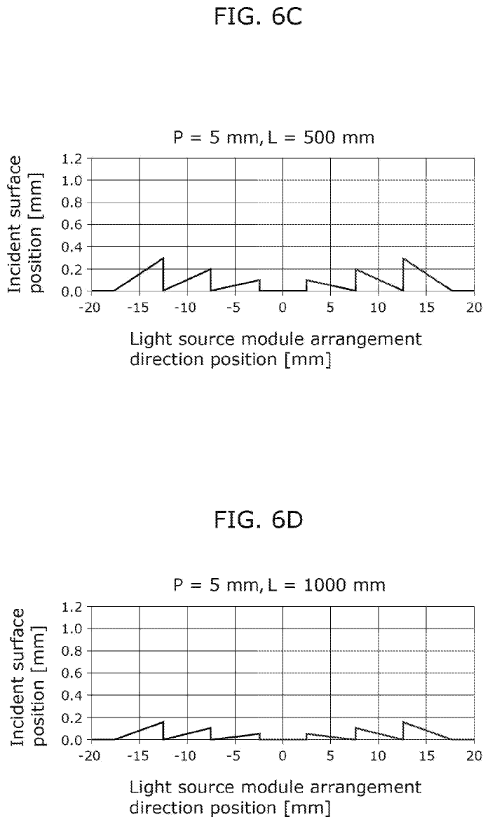

As shown in FIG. 5, emitted light beams 60a and 60e from semiconductor laser elements 10 included in light source modules 200a and 200e of semiconductor laser device 1 propagate in the same direction (Z-axis direction in FIG. 5) in the same plane. Then, the divergence angle of emitted light beams 60a and 60e in the first axis direction (X-axis direction in FIG. 5), which is the fast axis direction, is reduced by first lens 30 included in each light source module. Subsequently, the divergence angle of emitted light beams 60a and 60e in the second axis direction (Y-axis direction in FIG. 5), which is the slow axis direction, is reduced by second lens 40. Emitted light beams 60a and 60e, which are substantially parallel light beams by first lens 30 and second lens 40, are incident on deflection element 50. Emitted light beam 60a is deflected by plane 51a included in incident surface 52 of deflection element 50, and overlaps with emitted light beam 60e propagating in the same plane on wavelength dispersion element 70. The inclination of each plane of deflection element 50 with respect to the corresponding one of the emitted light beams is determined such that the emitted light beams overlap on wavelength dispersion element 70 according to distance L from the incident surface of deflection element 50 to wavelength dispersion element 70 and interval P between adjacent semiconductor laser elements 10. It should be noted that the position of incident surface 52 of deflection element 50 is defined as an incident reference position which is a position where the emitted light beam is substantially incident. Here, a design example of deflection element 50 according to the present embodiment will be described with reference to FIG. 6A to FIG. 6D. FIG. 6A to FIG. 6D are graphs showing design examples of a plurality of planes of deflection element 50 according to the present embodiment. FIG. 6A and FIG. 6B show the position of the incident surface of deflection element 50 in a case where interval P between adjacent semiconductor laser elements 10 is 10 mm and distance L from the incident surface of deflection element 50 to wavelength dispersion element 70 is 500 mm. FIG. 6B shows the position of the incident surface of deflection element 50 in a case where interval P is 10 mm and distance L is 1000 mm. FIG. 6C shows the position of the incident surface of deflection element 50 in a case where interval P is 5 mm and distance L is 500 mm. FIG. 6D shows the position of the incident surface of deflection element 50 in a case where interval P is 5 mm and distance L is 1000 mm. As shown in FIG. 6A to FIG. 6D, it is necessary to increase the inclination of the plane of deflection element 50 as interval P becomes smaller and distance L becomes smaller. As shown in FIG. 6A to FIG. 6D, deflection element 50 according to the present embodiment can be realized by designing each plane of incident surface 52 according to interval P and distance L.

Since deflection element 50 deflects emitted light beam 60a by plane 51a, it overlaps with emitted light beam 60e without being converged while remaining substantially parallel light. Emitted light beams 60a and 60e incident on wavelength dispersion element 70 in this way are wavelength-coupled by wavelength dispersion element 70 to become coupled light beam 61. Coupled light beam 61 is incident on partial reflection mirror 80, a part of coupled light beam 61 is reflected, and the other part is transmitted. Coupled light beam 61 reflected by partial reflection mirror 80 returns to wavelength dispersion element 70 again and is separated into emitted light beams 60a and 60e. Emitted light beams 60a and 60e are incident on light source modules 200a and 200e, are reflected by the highly reflective films provided on semiconductor laser elements 10, and are emitted from semiconductor laser elements 10 again, respectively.

In this way, emitted light beams 60a and 60e resonate in the external resonator formed between semiconductor laser elements 10 and partial reflection mirror 80. With this, laser beam 62, which is a part of coupled light beam 61, is emitted from partial reflection mirror 80.

As described above, in the present embodiment, since each of the emitted light beams is deflected by deflection element 50, even if the plurality of semiconductor laser elements 10 is arranged so that the interval (corresponding to interval P shown in FIG. 5) between the plurality of semiconductor laser elements 10 is small, it is possible to overlap a plurality of emitted light beams on wavelength dispersion element 70 by appropriately setting the inclinations of the plurality of planes of deflection element 50. With this, the number of semiconductor laser elements 10 per unit area can be increased, so that the number of semiconductor laser elements 10 that can be arranged in semiconductor laser device 1 can also be increased, and the increased output of semiconductor laser device 1 can be realized. In addition, since the plurality of emitted light beams are not converged by deflection element 50, they can be incident on the wavelength dispersion element in a state of substantially parallel light. Therefore, since the beam diameter on wavelength dispersion element 70 can be increased, even if a plurality of emitted light beams 60a to 60i are overlapped, the light density can be suppressed as compared with the case where a plurality of converged light beams are overlapped. With this, it is possible to overlap the emitted light beams from more semiconductor laser elements while suppressing damage to wavelength dispersion element 70, so that the increased output of semiconductor laser device 1 can be realized.

In addition, since each emitted light incident on wavelength dispersion element 70 can be made into parallel light having a small incident angle distribution, each laser beam can be coupled in the state of parallel light by wavelength dispersion element 70. With this, a high-luminance laser beam with high beam quality can be obtained as the emitted light beam output from the partially reflected mirror.

In addition, in the present embodiment, the plurality of semiconductor laser elements 10 are arranged at equal intervals in the first axis direction, which is the fast axis direction. Here, the beam parameter product of the emitted light beam of semiconductor laser element 10 in the fast axis direction may be 1 [mm·mrad] or less. In this case, the beam parameter product in the axis direction, in which the plurality of emitted light beams are overlapped, of the two axis directions of the plurality of emitted light beams, is 1 [mm·mrad] or less, so that even if the overlap of the respective emitted light beams is deviated, the allowable range of deviation becomes large. With this, the deterioration of the beam quality in the axis direction coupled by the wavelength dispersion can be suppressed, so that semiconductor laser device 1 capable of outputting a high-luminance laser beam can be realized.

In addition, in the present embodiment, as shown in FIG. 3B, the plurality of semiconductor laser elements 10 are each mounted on a plurality of packages 20 via sub-mounts 11 comprising an electrically insulating material. The plurality of lead pins 23 and 24 and the plurality of packages 20 are insulated from each other, and the plurality of semiconductor laser elements 10 are connected in series, and are current-driven. With this, the same current can be supplied to the plurality of semiconductor laser elements 10, so that the outputs of respective semiconductor laser elements 10 can be made uniform.

### Embodiment 2

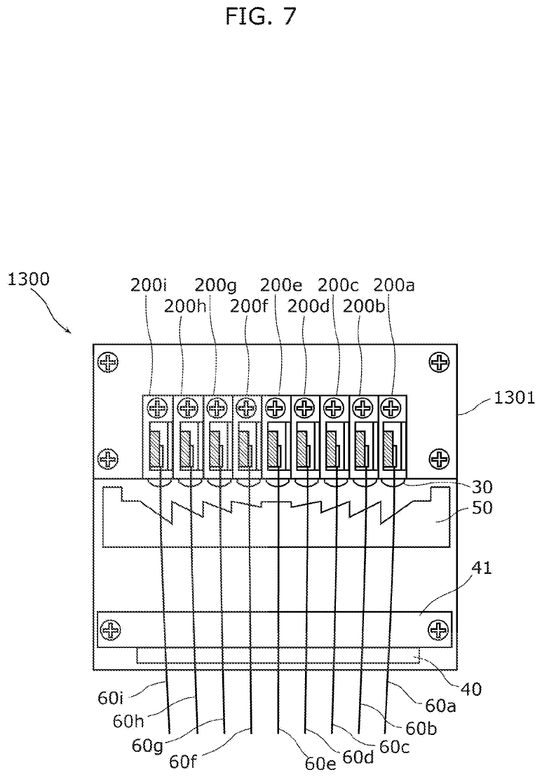

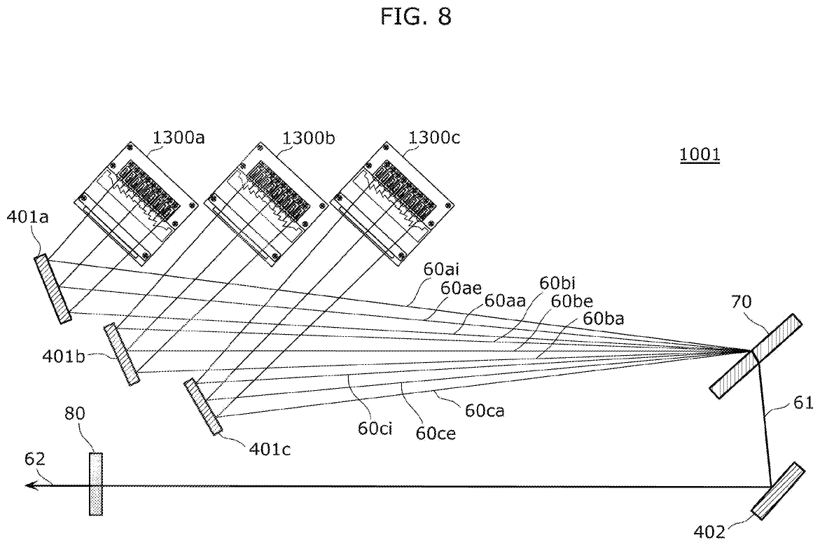

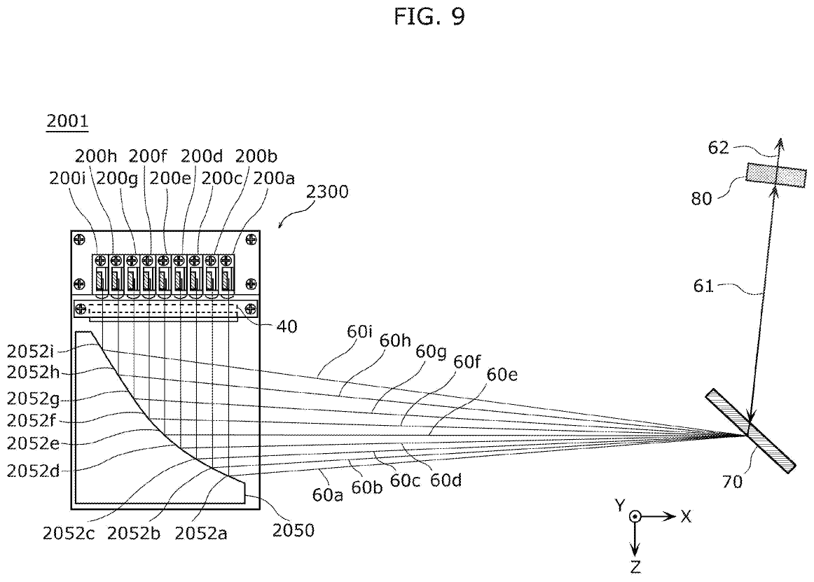

The semiconductor laser device according to Embodiment 2 will be described. The semiconductor laser device according to the present embodiment is different from semiconductor laser device 1 according to Embodiment 1 mainly in the arrangement of deflection element 50 and second lens 40. Hereinafter, the semiconductor laser device according to the present embodiment will be described with reference to FIG. 7 and FIG. 8 focusing on the differences from semiconductor laser device 1 according to Embodiment 1.

FIG. 7 is a schematic top view showing the configuration of light source unit 1300 according to the present embodiment. FIG. 8 is a schematic top view showing the configuration of semiconductor laser device 1001 according to the present embodiment.

As shown in FIG. 8, semiconductor laser device 1001 according to the present embodiment includes three light source units 1300a, 1300b, and 1300c, wavelength dispersion element 70, reflection mirrors 401a, 401b, 401c, and 402, and partial reflection mirror 80.

Three light source units 1300a, 1300b, and 1300c all have the same configuration as light source unit 1300 shown in FIG. 7.

As shown in FIG. 7, light source unit 1300 according to the present embodiment includes unit base 1301, a plurality of light source modules 200a to 200i, deflection element 50, second lens 40, and lens holder 41. It should be noted that although not shown, light source unit 1300 includes circuit board 310 like light source unit 300 according to Embodiment 1.

As shown in FIG. 7, light source unit 1300 according to Embodiment 1 is different from light source unit 300 according to Embodiment 1 in that the position of second lens 40 and lens holder 41 and the position of deflection element 50 are interchanged. Along with this, the configuration such as the position of the screw hole of unit base 1301 is changed from the configuration of unit base 301 according to Embodiment 1.

Similar to light source unit 300 according to Embodiment 1, even with light source units 1300a, 1300b, and 1300c according to the present embodiment, emitted light beams 60aa to 60ai, 60ba to 60bi, and 60ca to 60ci, which are substantially parallel light beams, can be overlapped on wavelength dispersion element 70 via reflection mirrors 401a, 401b, and 401c. In addition, in the present embodiment, since the emitted light beams from three light source units 1300a, 1300b, and 1300c are overlapped, a laser beam having higher luminance than that of Embodiment 1 can be obtained.

In addition, although an example in which a transmissive diffraction grating is used as wavelength dispersion element 70 and an example in which reflection mirrors 401a, 401b, 401c, and 402 are provided in the external resonator are shown in the present embodiment, the same effect as that of semiconductor laser device 1 according to Embodiment 1 is also exhibited in such a configuration. In addition, by using reflection mirrors 401a, 401b, and 401c in the external resonator, the distance from deflection element 50 to wavelength dispersion element 70 can be increased while suppressing the expansion of the dimensions of semiconductor laser device 1001. With this, the inclination of each plane of deflection element 50 can be reduced while suppressing the expansion of the dimensions of semiconductor laser device 1001.

### Embodiment 3

The semiconductor laser device according to Embodiment 3 will be described. The semiconductor laser device according to the present embodiment is different from semiconductor laser device 1 according to Embodiment 1 mainly in that a plurality of planes of the deflection element reflect a plurality of emitted light beams, respectively. Hereinafter, the semiconductor laser device according to the present embodiment will be described with reference to FIG. 9, focusing on the differences from semiconductor laser device 1 according to Embodiment 1. FIG. 9 is a schematic top view showing the configuration of semiconductor laser device 2001 according to the present embodiment.

As shown in FIG. 9, semiconductor laser device 2001 according to the present embodiment includes light source unit 2300, wavelength dispersion element 70, and partial reflection mirror 80.

Light source unit 2300 according to the present embodiment is different from light source unit 300 according to Embodiment 1 in the configuration of deflection element 2050.

Similar to deflection element 50 according to Embodiment 1, deflection element 2050 according to the present embodiment includes a plurality of planes 2052a to 2052i corresponding to the plurality of emitted light beams 60a to 60i, respectively. The plurality of planes 2052a to 2052i are inclined with respect to the optical axes of the plurality of emitted light beams 60a to 60i, respectively. In the present embodiment, the plurality of planes 2052a to 2052i are reflective surfaces that reflect the plurality of emitted light beams 60a to 60i, respectively. Deflection element 2050 is formed, for example, by forming a metal film to be a reflective film on glass or the like on which a plurality of flat surfaces are formed.

Even with deflection element 2050 having such a configuration, it is possible to overlap a plurality of emitted light beams 60a to 60i on wavelength dispersion element 70 by adjusting each inclination of the planes 2052a to 2052i. Therefore, the same effect as that of semiconductor laser device 1 according to Embodiment 1 is also exhibited in semiconductor laser device 2001 according to the present embodiment.

### Embodiment 4

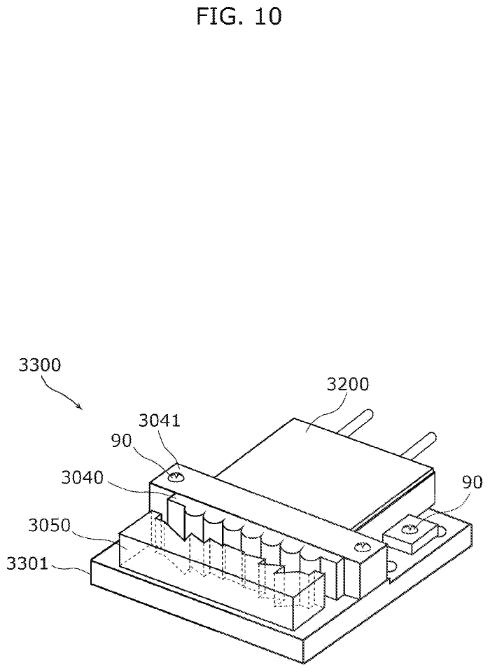

The semiconductor laser device according to Embodiment 4 will be described. The semiconductor laser device according to the present embodiment is different from semiconductor laser device 1 according to Embodiment 1 in that a plurality of semiconductor laser elements are arranged in the second axis direction and a plurality of semiconductor laser elements are arranged in one package. Since the semiconductor laser device according to the present embodiment has the same configuration as semiconductor laser device 1 according to Embodiment 1 except for the light source unit, the light source unit of the semiconductor laser device according to the present embodiment will be described below with reference to FIG. 10 to FIG. 13 focusing on the differences from light source unit 300 according to Embodiment 1.

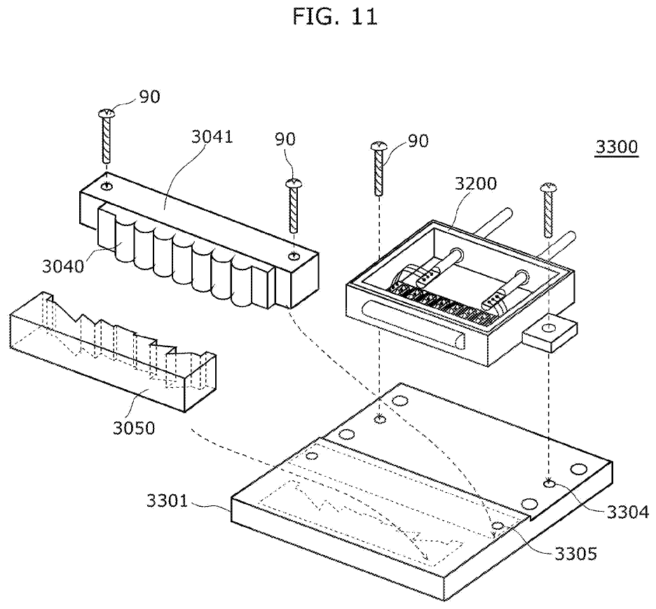

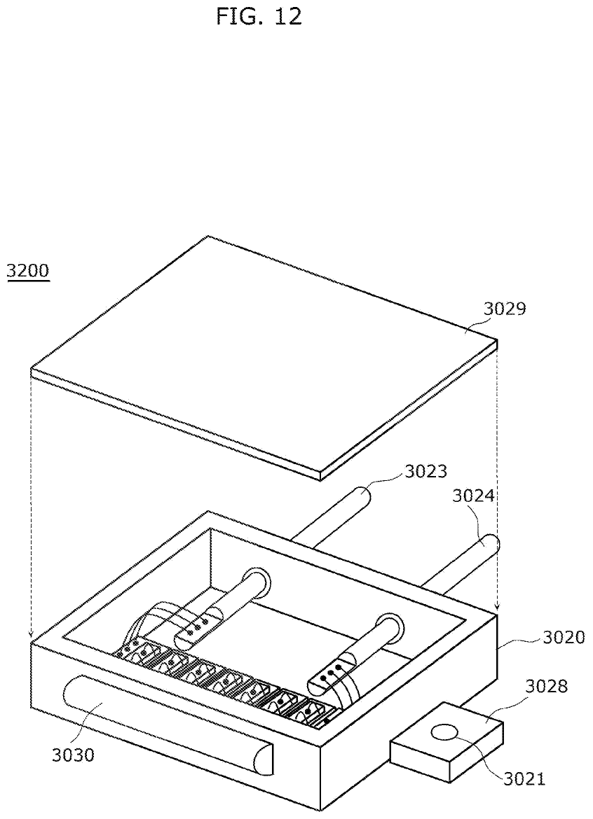

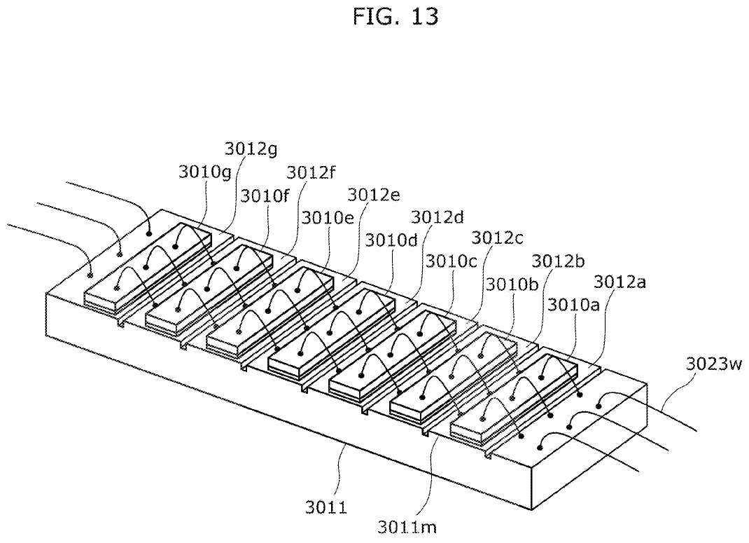

FIG. 10 is a schematic perspective view showing the appearance of light source unit 3300 according to the present embodiment. FIG. 11 is an exploded perspective view showing the configuration of light source unit 3300 according to the present embodiment. FIG. 12 is an exploded perspective view showing the configuration of light source module 3200 according to the present embodiment. FIG. 13 is a perspective view showing the appearance of the plurality of semiconductor laser elements 3010a to 3010g and sub-mount 3011 according to the present embodiment.

As shown in FIG. 10, light source unit 3300 according to the present embodiment includes light source module 3200, second lens 3040, lens holder 3041, deflection element 3050, and unit base 3301.

Deflection element 3050 according to the present embodiment has the same configuration as deflection element 50 according to Embodiment 1, except that the incident surface includes seven planes. As shown in FIG. 10 and FIG. 11, the bottom surface of deflection element 3050 is bonded to unit base 3301.

Light source module 3200 according to the present embodiment is a module having a plurality of semiconductor laser elements. Light source module 3200 according to the present embodiment includes package 3020 and first lens 3030 as shown in FIG. 12. In addition, light source module 3200 further includes a plurality of semiconductor laser elements 3010a to 3010g shown in FIG. 13 and one sub-mount 3011. In the present embodiment, it includes seven semiconductor laser elements 3010a to 3010g. The beam parameter products in the first axis direction and the second axis direction of each of the plurality of emitted light beams, which is emitted by each of the plurality of semiconductor laser elements 3010a to 3010g, are 1 [mm·mrad] or less. In this way, since the beam parameter product of the plurality of emitted light beams in the second axis direction is sufficiently small, the plurality of semiconductor laser elements 3010a to 3010g may be arranged in the second axis direction, as shown in FIG. 13. In the present embodiment, the plurality of semiconductor laser elements 3010a to 3010g are arranged in the second axis direction. More specifically, the plurality of semiconductor laser elements 3010a to 3010g are arranged at equal intervals in the second axis direction. Also in this case, the beam parameter product in the axis direction, in which the plurality of emitted light beams of semiconductor laser elements 3010a to 3010g are overlapped, of the two axis directions of the plurality of emitted light beams, is 1 [mm·mrad] or less, so that even if the overlap of the respective emitted light beams is deviated, the allowable range of deviation becomes large. With this, the deterioration of the beam quality in the axis direction coupled by the wavelength dispersion can be suppressed, so that a semiconductor laser device capable of outputting a high-luminance laser beam can be realized.

As shown in FIG. 12, package 3020 according to the present embodiment is a case in which a plurality of semiconductor laser elements 3010a to 3010g are mounted and comprise a metal material. In the present embodiment, package 3020 has a rectangular parallelepiped outer shape and includes lid 3029. It should be noted that the plurality of semiconductor laser elements 3010a to 3010g are junction-down mounted on sub-mount 3011. That is, the p-side electrodes (not shown) of the plurality of semiconductor laser elements 3010a to 3010g are connected to sub-mount 3011.

Package 3020 according to the present embodiment airtightly seals the plurality of semiconductor laser elements 3010a to 3010g. With this, the atmosphere inside package 3020 can be controlled, so that the deterioration of semiconductor laser elements 3010a to 3010g can be suppressed. In particular, when semiconductor laser elements 3010a to 3010g emit laser beams having a relatively short wavelength such as blue light or ultraviolet light, the deposition of siloxane onto semiconductor laser elements 3010a to 3010g or the like can be reduced by suppressing the inflow of siloxane into package 3020.

Package 3020 includes a plurality of lead pins 3023 and 3024 that supply electric power to the plurality of semiconductor laser elements 3010a to 3010g. Electric power is supplied to the plurality of semiconductor laser elements 3010a to 3010g by lead pin 3023 and lead pin 3024.

First lens 3030 is arranged in package 3020. First lens 3030 is a cylindrical lens that reduces the divergence of the plurality of semiconductor laser elements 3010a to 3010g in the first axis direction. In the present embodiment, first lens 3030 is a fast axis collimator that substantially parallelizes the emitted light beams from the plurality of semiconductor laser elements 3010a to 3010g.

In the present embodiment, the plurality of semiconductor laser elements 3010a to 3010g are mounted on one package 3020 via one sub-mount 3011. In this way, by mounting the plurality of semiconductor laser elements 3010a to 3010g on one sub-mount 3011, it is possible to reduce the deviation of the optical axes of the plurality of emitted light beams. Therefore, the semiconductor laser device can output a laser beam having higher luminance.

The plurality of semiconductor laser elements 3010a to 3010g are connected in series with each other by conductive wires 3023w. More specifically, lead pin 3023 is connected to the n-side electrode of semiconductor laser element 3010a by conductive wires 3023w, and conductive film 3012a connected to the p-side electrode of semiconductor laser element 3010a is connected to the n-side electrode of semiconductor laser element 3010b by conductive wires 3023w. Hereinafter, in the same manner, the plurality of semiconductor laser elements 3010a to 3010g are connected in series, and conductive film 3012g connected to the p-side electrode of semiconductor laser element 3010g is connected to lead pin 3024 by conductive wires 3023w. This makes it possible to current-drive the plurality of semiconductor laser elements 3010a to 3010g.

Sub-mount 3011 according to the present embodiment comprises an electrically insulating material having high thermal conductivity. Sub-mount 3011 comprises, for example, SiC, AlN, diamond or the like. A plurality of conductive films 3012a to 3012g are formed on upper surface 3011m of sub-mount 3011 at positions where the plurality of semiconductor laser elements 3010a to 3010g are mounted, respectively. The plurality of conductive films 3012a to 3012g are insulated from one another. In order to further ensure the insulation of the plurality of conductive films 3012a to 3012g, grooves may be formed between adjacent conductive films on upper surface 3011m of sub-mount 3011 as shown in FIG. 13.

Second lens 3040 is an optical element in which a plurality of cylindrical lenses that reduce the divergence of the plurality of semiconductor laser elements 3010a to 3010g in the second axis direction are integrated. In the present embodiment, second lens 3040 is a slow axis collimator that substantially parallelizes the emitted light beams from the plurality of semiconductor laser elements 3010a to 3010g in the second axis direction. Second lens 3040 is fixed to unit base 3301 via lens holder 3041. Through holes are formed in lens holder 3041, and screws 90 inserted into the through holes are screwed into fixing holes 3305 formed in unit base 3301, so that lens holder 3041 and second lens 3040 are fixed to unit-base 3301.

As shown in FIG. 12, light source module 3200 includes plate-shaped fixture 3028. Through hole 3021 is formed in fixture 3028, and light source module 3200 is fixed to unit base 3301 by inserting screw 90 into through hole 3021 and screwing screw 90 into fixing hole 3304 (see FIG. 11) formed in unit base 3301.

The same effect as that according to Embodiment 1 is also exhibited in the semiconductor laser device including light source unit 3300 according to the present embodiment.

It should be noted that the present embodiment has a form in which a plurality of semiconductor laser elements are mounted on a sub-mount, but as long as the beam parameter products in the first axis direction and the second axis direction of each of the plurality of emitted light beams are 1 [mm·mrad] or less, an array of semiconductor laser elements in which a plurality of semiconductor laser elements are formed on the same substrate can also be used.

### (Variations, etc.)

The semiconductor laser device according to the present disclosure has been described above based on each embodiment, but the present disclosure is not limited to each of the above embodiments.

For example, in each of the above embodiments, the plurality of semiconductor laser elements are current-driven, but the plurality of semiconductor laser elements may be voltage-driven. Specifically, the plurality of semiconductor laser devices may be mounted in the plurality of packages via sub-mounts comprising a conductive material, respectively, one of the plurality of lead pins may have the same potential as the plurality of packages, and the plurality of semiconductor laser devices may be voltage-driven. For example, the n-side electrodes of the plurality of semiconductor laser elements are mounted on the sub-mounts comprising a conductive material, and have the same potential as the packages on which the sub-mounts are mounted. In this case, the plurality of semiconductor laser elements may be voltage-driven by applying a potential higher than the potential of the packages to the p-side electrodes of the plurality of semiconductor laser elements.

In addition, in each of the above embodiments, each of the plurality of semiconductor laser elements includes a single semiconductor light emitting element, but the configuration of the plurality of semiconductor laser elements is not limited thereto. For example, each of the plurality of semiconductor laser elements may include a semiconductor light emitting element and a reflecting member that forms an external resonator. In addition, the external resonator may include a wavelength selection member that selects the wavelength of the emitted light. For example, the external resonator may include a transmissive diffraction grating or the like as a wavelength selection member that functions as a partial reflection mirror. In this case, the external resonator may be included between the transmissive diffraction grating and one end of the semiconductor light emitting element.

In addition, forms obtained by making various modifications to each of the above embodiments that can be conceived by those skilled in the art, as well as forms realized by combining structural components and functions in each of the above embodiments, without materially departing from the spirit of the present disclosure, are included in the present disclosure.

### INDUSTRIAL APPLICABILITY

The semiconductor laser device of the present disclosure can be applied to, for example, a laser processing machine or the like as a high-output and highly efficient light source.

1. A semiconductor laser device, comprising:
semiconductor laser elements each of which emits a light beam having a different wavelength;
a deflection element that deflects at least one of emitted light beams from the semiconductor laser elements; and
a wavelength dispersion element that wavelength-couples the emitted light beams onto a same optical axis,
wherein the deflection element has planes each corresponding to the emitted light beams; and
the emitted light beams overlap one another on the wavelength dispersion element.

2. The semiconductor laser device according to claim 1,
wherein the emitted light beams each have a divergence angle in a first axis direction and a divergence angle in a second axis direction orthogonal to the first axis direction,
the semiconductor laser device further comprises lenses each of which converts at least one of the divergence angle in the first axis direction or the divergence angle in the second axis direction,
at least one plane among the planes is inclined with respect to an optical axis of a corresponding one of the emitted light beams, and
the semiconductor laser elements are arranged in one axis direction of the first axis direction and the second axis direction.

3. The semiconductor laser device according to claim 1, further comprising:
a partial reflection mirror that reflects a part of the emitted light beams wavelength-coupled by the wavelength dispersion element, transmits another part of the emitted light beams, and forms an external resonator with the semiconductor laser elements.

4. The semiconductor laser device according to claim 2,
wherein the lenses include a first lens that reduces the divergence angle of a laser beam in the first axis direction.

5. The semiconductor laser device according to claim 4,
wherein the lenses include a second lens that reduces the divergence angle of the emitted light beams in the second axis direction.

6. The semiconductor laser device according to claim 5,
wherein the second lens is disposed between the first lens and the wavelength dispersion element.

7. The semiconductor laser device according to claim 2,
wherein a beam parameter product of each of the emitted light beams is 1 [mm·mrad] or less in the one axis direction.

8. The semiconductor laser device according to claim 1,
wherein the deflection element has an incident surface on which the emitted light beams are incident, and an emitting surface from which the emitted light beams incident on the incident surface are emitted, and
the planes are transmission surfaces that transmit the emitted light beams, and are included in at least one of the incident surface or the emitting surface.

9. The semiconductor laser device according to claim 1,
wherein the planes are reflective surfaces that reflect the emitted light beams, respectively.

10. The semiconductor laser device according to claim 5,
wherein the one axis direction is the first axis direction,
the first lens is a fast axis collimator, and
the second lens is a slow axis collimator.

11. The semiconductor laser device according to claim 10, further comprising:
packages in each of which a corresponding one of the semiconductor laser elements is mounted, and which comprise a metal material,
wherein each of the packages includes lead pins that supply electric power to the semiconductor laser element mounted in the package among the semiconductor laser elements are included,
the first lens is disposed at each of light emission portions of the packages,
each of the packages has a mounting surface on which the semiconductor laser element is mounted, and
each of the packages includes two planes parallel to the mounting surface, and a distance between the two planes corresponds to a thickness of the package, and is equal to each of intervals at which the semiconductor laser elements are arranged.

12. The semiconductor laser device according to claim 11,
wherein the semiconductor laser elements are mounted in the packages via sub-mounts comprising a conductive material,
one of the lead pins has a potential identical to a potential of the packages, and
the semiconductor laser elements are voltage-driven.

13. The semiconductor laser device according to claim 11,
wherein the semiconductor laser elements are each mounted in corresponding one of the packages via a corresponding one of sub-mounts comprising an electrically insulating material,
the lead pins are insulated from a corresponding one of the packages, and
the semiconductor laser elements are current-driven.

14. The semiconductor laser device according to claim 11,
wherein the packages each airtightly seal a corresponding one of the semiconductor laser elements.

15. The semiconductor laser device according to claim 5,
wherein a beam parameter product of each of the emitted light beams in the first axis direction and the second axis direction is 1 [mm·mrad] or less,
the semiconductor laser elements are arranged in the second axis direction,
the first lens is a fast axis collimator, and
the second lens is a slow axis collimator.

16. The semiconductor laser device according to claim 15, further comprising:
one package in which the semiconductor laser elements are mounted, and which comprises a metal material,
wherein the one package includes lead pins that supply electric power to the semiconductor laser elements, and
the first lens is disposed in the one package.

17. The semiconductor laser device according to claim 16,
wherein the semiconductor laser elements are mounted in the one package via one sub-mount.

18. The semiconductor laser device according to claim 16,
wherein the one package airtightly seals the semiconductor laser elements.
